(19) United States
(12) Patent Application Publication
(10) Pub. No.: US 2024/0275341 A1
(43) Pub. Date: Aug. 15, 2024

(54) Signal transmission apparatus and power amplification output circuit

(71) Applicant: REALTEK SEMICONDUCTOR CORPORATION, Hsinchu (TW)

(72) Inventor: SHENG-CIANG TU, Hsinchu (TW)

(21) Appl. No.: 18/416,939

(22) Filed: Jan. 19, 2024

(30) Foreign Application Priority Data
Feb. 10, 2023 (TW) 112104860

(51) Int. Cl. H03F 3/24; H03F 1/22; H03F 3/45

(52) U.S. Cl. CPC H03F 3/245; H03F 1/223; H03F 3/45179; H03F 2200/451; H03F 2200/541

(57) ABSTRACT

The present disclosure discloses a power amplification output circuit. An output transformer includes a first side inductor and a second side inductor. A cascode power amplifier is electrically coupled to the first side inductor. An inverter-type power amplifier is electrically coupled to the first side inductor. The cascode power amplifier is activated under a normal power output mode to receive, amplify and output a differential radio frequency input signals from cascode differential input terminals to the output transformer through cascode differential output terminals further to an antenna through the second side inductor. The inverter-type power amplifier is activated under a back off power output mode to receive, amplify and output the differential radio frequency input signals from inverter-type differential input terminals to the output transformer through inverter-type differential output terminals further to the antenna through the second side inductor.

### BACKGROUND OF THE INVENTION

### 1. Field of the Invention

The present disclosure relates to a signal transmission apparatus and a power amplification output circuit.

### 2. Description of Related Art

Wireless communication technologies become the mainstream communication technology since physical wires are not required to perform communication. In various kinds of wireless communication technologies, Bluetooth has developed for over 30 years and is important in various fields of telecom, computer, network and consumer electronics.

In recent years, in order to maintain the same communication range of conventional Bluetooth technology and reduce the power consumption and cost greatly at the same time, Bluetooth Low Energy (BLE) technology is developed and is widely used in products that have small sizes and demand power-saving. In different application requirements, the electronic apparatuses equipped with BLE technology generate outputs of different power. However, under different power output modes, the power amplifiers of such electronic apparatuses can not keep the conversion efficiency that converts a direct current input to an alternating current output.

### SUMMARY OF THE INVENTION

In consideration of the problem of the prior art, an object of the present disclosure is to provide a signal transmission apparatus and a power amplification output circuit.

The present invention discloses a power amplification output circuit that includes an output transformer, a cascode power amplifier and an inverter-type power amplifier. The output transformer includes a first side inductor and a second side inductor. The cascode power amplifier is electrically coupled between a pair of cascode differential input terminals and a pair of cascode differential output terminals and is electrically coupled to the first side inductor through the pair of cascode differential output terminals. The inverter-type power amplifier is electrically coupled between a pair of inverter-type differential input terminals and a pair of inverter-type differential output terminals and is electrically coupled to the first side inductor through the pair of inverter-type differential output terminals. The cascode power amplifier is activated under a normal power output mode to receive a pair of differential radio frequency input signals through the pair of cascode differential input terminals to perform power amplifying to the pair of differential radio frequency input signals and output the amplified differential radio frequency input signals to the output transformer through the pair of cascode differential output terminals and further to an antenna through the second side inductor. The inverter-type power amplifier is activated under a back off power output mode to receive the pair of differential radio frequency input signals through the pair of inverter-type differential input terminals to perform power amplifying to the pair of differential radio frequency input signals and output the amplified differential radio frequency input signals to the output transformer through the pair of inverter-type differential output terminals and further to the antenna through the second side inductor.

The present invention also discloses signal transmission apparatus that includes a signal source circuit, a power amplification output circuit and a mode control circuit. The signal source circuit is configured to generate a pair of differential radio frequency input signals. The power amplification output circuit includes an output transformer, a cascode power amplifier and an inverter-type power amplifier. The output transformer includes a first side inductor and a second side inductor. The cascode power amplifier is electrically coupled between a pair of cascode differential input terminals and a pair of cascode differential output terminals and is electrically coupled to the first side inductor through the pair of cascode differential output terminals. The inverter-type power amplifier is electrically coupled between a pair of inverter-type differential input terminals and a pair of inverter-type differential output terminals and is electrically coupled to the first side inductor through the pair of inverter-type differential output terminals. The mode control circuit is configured to generate a mode control signal to the cascode power amplifier and the inverter-type power amplifier such that the cascode power amplifier and the inverter-type power amplifier operate in one of a normal power output mode and a back off power output mode. The cascode power amplifier is activated under the normal power output mode to receive the pair of differential radio frequency input signals through the pair of cascode differential input terminals to perform power amplifying to the pair of differential radio frequency input signals and output the amplified differential radio frequency input signals to the output transformer through the pair of cascode differential output terminals and further to an antenna through the second side inductor. The inverter-type power amplifier is activated under the back off power output mode to receive the pair of differential radio frequency input signals through the pair of inverter-type differential input terminals to perform power amplifying to the pair of differential radio frequency input signals and output the amplified differential radio frequency input signals to the output transformer through the pair of inverter-type differential output terminals and further to the antenna through the second side inductor.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a block diagram of a communication system according to an embodiment of the present invention.

FIG. 2A illustrates a more detailed circuit diagram of the cascode power amplifier, the output transformer and the antenna in FIG. 1 according to an embodiment of the present invention.

FIG. 2B illustrates a diagram of a waveform of the differential radio frequency output signal outputted after the cascode power amplifier performs power amplifying according to an embodiment of the present invention.

FIG. 3A illustrates a more detailed circuit diagram of the inverter-type power amplifier, the output transformer and the antenna in FIG. 1 according to an embodiment of the present invention.

FIG. 3B illustrates a diagram of a waveform of the differential radio frequency output signal outputted after the inverter-type power amplifier performs power amplifying according to an embodiment of the present invention.

FIG. 4 illustrates a diagram of the relation between the output power and a drain efficiency of each of the cascode power amplifier and the inverter-type power amplifier according to an embodiment of the present invention.

### DETAILED DESCRIPTION OF THE PREFERRED EMBODIMENTS

An aspect of the present invention is to provide a signal transmission apparatus and a power amplification output circuit that perform power amplifying on differential radio frequency (RF) input signals by using a cascode power amplifier and an inverter-type power amplifier respectively under a normal power output mode and a back off power output mode. The overload caused by the input power of the differential radio frequency input signals that is too large can be avoided under the back off power output mode of the power amplification output circuit, and the drain efficiency under the back off power output mode can be kept to be the same as the drain efficiency under the normal power output mode.

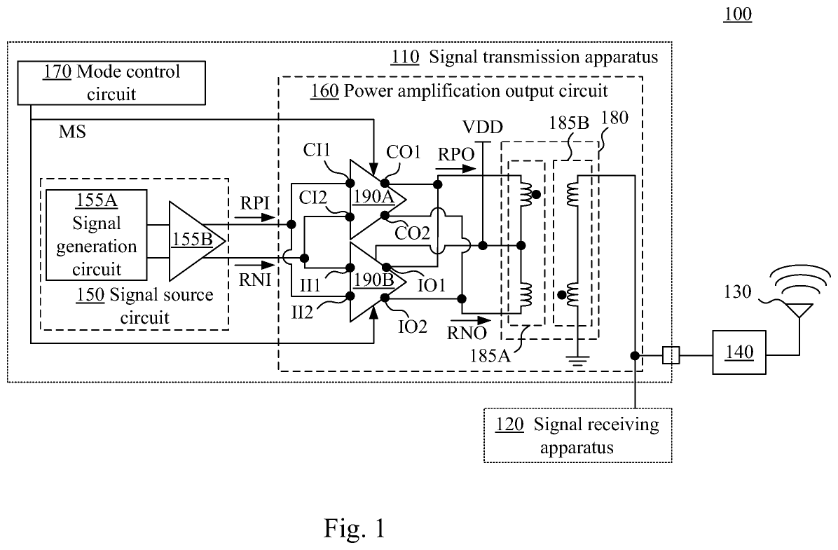

Reference is now made to FIG. 1. FIG. 1 illustrates a block diagram of a communication system 100 according to an embodiment of the present invention. In an embodiment, the communication system 100 is configured to perform communication based on Bluetooth Low Energy (BLE) technology.

The communication system 100 includes signal transmission apparatus (TX) 110, a signal receiving apparatus (RX) 120 and an antenna 130. In an embodiment, the signal transmission apparatus 110 and the signal receiving apparatus 120 can be electrically coupled to the antenna 130 through a matching circuit 140, in which the matching circuit 140 is configured to provide an impedance matching mechanism. The signal transmission apparatus 110 performs signal transmission through the matching circuit 140 and the antenna 130. The signal receiving apparatus 120 performs signal receiving through the antenna 130 and the matching circuit 140.

The configuration of the signal transmission apparatus 110 is described in the following paragraphs.

The signal transmission apparatus 110 includes a signal source circuit 150, a power amplification output circuit 160 and a mode control circuit 170.

The signal source circuit 150 includes a signal generation circuit 155A and a signal processing circuit 155B. The signal generation circuit 155A performs signal generation and the signal processing circuit 155B performs signal processing so as to generate a pair of differential radio frequency input signals RPI and RNI.

In an embodiment, the signal generation circuit 155A may include such as but not limited to a digital signal processing circuit and a digital-to-analog conversion circuit to perform signal generation. The signal processing circuit 155B may include such as but not limited to a frequency division circuit and a driving circuit to perform frequency division and amplification on the signal generated by the signal generation circuit 155A to further generate the differential radio frequency input signals RPI and RNI.

The power amplification output circuit 160 includes an output transformer 180, a cascode power amplifier 190A and an inverter-type power amplifier 190B.

The output transformer 180 includes a first side inductor 185A and a second side inductor 185B. The first side inductor 185A is electrically coupled to the cascode power amplifier 190A and the inverter-type power amplifier 190B. The second side inductor 185B is electrically coupled to the antenna 130. It is appreciated that in different embodiments, circuit components (not illustrated in the figure) used to perform filtering and matching can be selectively included between the second side inductor 185B and the antenna 130.

By using the configuration described above, the first side inductor 185A can receive the signal from the cascode power amplifier 190A and the inverter-type power amplifier 190B. Through the coupling with the second side inductor 185B, the signal can be transmitted to the antenna 130 from the second side inductor 185B and further outputted by the antenna 130.

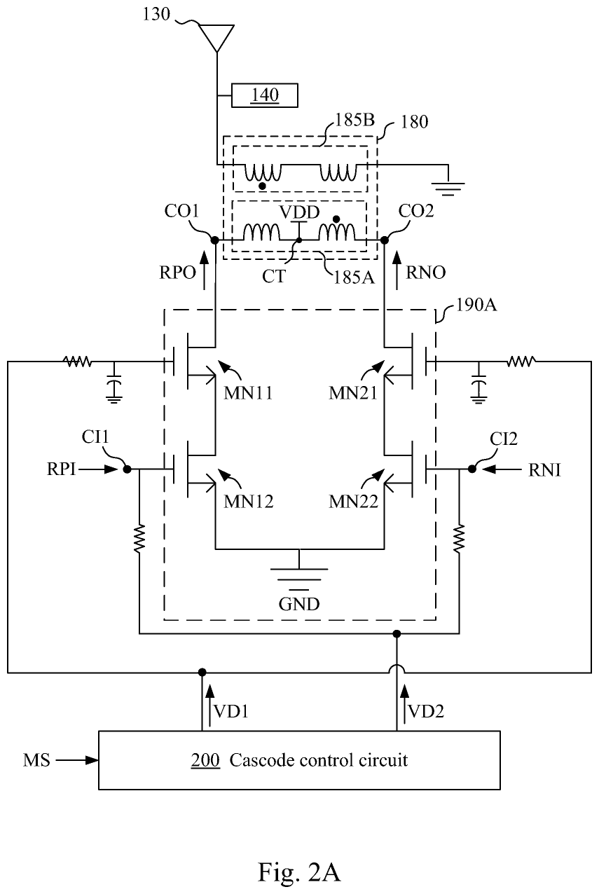

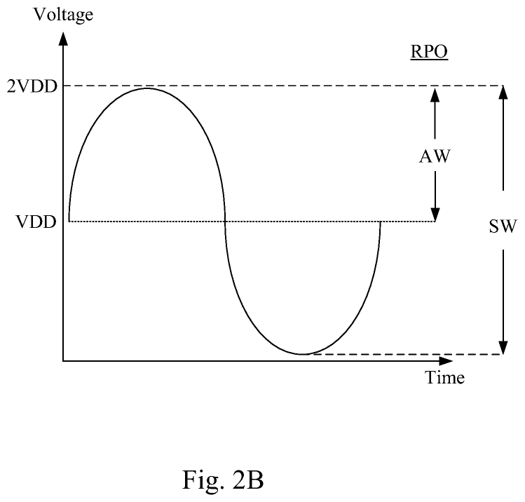

Reference is now made to FIG. 2A. FIG. 2A illustrates a more detailed circuit diagram of the cascode power amplifier 190A, the output transformer 180 and the antenna 130 in FIG. 1 according to an embodiment of the present invention.

As illustrated in FIG. 2A, the cascode power amplifier 190A is electrically coupled between a pair of cascode differential input terminals CI1 and CI2 and a pair of cascode differential output terminals CO1 and CO2 and is electrically coupled to the first side inductor 185A through the cascode differential output terminals CO1 and CO2.

The cascode power amplifier 190A includes a first cascode branch circuit and a second cascode branch circuit. The first cascode branch circuit includes a first upper N-type transistor MN11 and a first lower N-type transistor MN12 coupled in series between a first terminal (which is the cascode differential input terminal CO1) of the cascode differential input terminals and a ground terminal GND. The second cascode branch circuit includes a second upper N-type transistor MN21 and a second lower N-type transistor MN22 coupled in series between a second terminal (which is the cascode differential input terminal CO2) of the cascode differential input terminals and the ground terminal GND.

The first upper N-type transistor MN11 and the second upper N-type transistor MN21 are electrically coupled to a power supply terminal VDD through a center tap CT of the first side inductor 185A. In an embodiment, the power supply terminal VDD may provide a power having a voltage of such as, but not limited to 1.2 volts.

The first upper N-type transistor MN11 and the second upper N-type transistor MN21 are controlled by an upper driving voltage VD1. More specifically, the gates of the first upper N-type transistor MN11 and the second upper N-type transistor MN21 are configured to receive the upper driving voltage VD1 that is a direct current (DC) voltage to be turned on or turned off according to the upper driving voltage VD1.

The first lower N-type transistor MN12 and the second lower N-type transistor MN22 are controlled by a lower driving voltage VD2. More specifically, the gates of the first lower N-type transistor MN12 and the second lower N-type transistor MN22 are configured to receive the lower driving voltage VD2 that is a direct current voltage to be turned on or turned off according to the lower driving voltage VD2.

Moreover, the first lower N-type transistor MN12 and the second lower N-type transistor MN22 receive differential radio frequency input signals RPI and RNI from the cascode differential input terminals CI1 and CI2. More specifically, the gate of the first lower N-type transistor MN12 is configured to receive the differential radio frequency input signal RPI that is an alternating current (AC) voltage. The gate of the second lower N-type transistor MN22 is configured to receive the differential radio frequency input signal RNI that is an alternating current voltage.

The cascode power amplifier 190A further includes a cascode control circuit 200 configured to generate the upper driving voltage VD1 and the lower driving voltage VD2 according to the mode control signal MS to control the turn-on and turn-off of each of the transistors. The mode control circuit 170 is configured to generate the mode control signal MS to a cascode control circuit 200 of the cascode power amplifier 190A such that the cascode power amplifier 190A operates in one of a normal power output mode and a back off power output mode. In an embodiment, the mode control circuit 170 may determine the signal power to be outputted currently according to a front end control circuit to generate the mode control signal MS.

More specifically, under the normal power output mode, the cascode control circuit 200 generates the upper driving voltage VD1 and the lower driving voltage VD2 each having a non-ground voltage level according to the mode control signal MS such that the first upper N-type transistor MN11, the first lower N-type transistor MN12, the second upper N-type transistor MN21 and the second lower N-type transistor MN22 turn on.

As a result, the cascode power amplifier 190A is activated under the normal power output mode to receive the differential radio frequency input signals RPI and RNI through the cascode differential input terminals CI1 and CI2 to perform power amplifying thereon and output the amplified differential radio frequency output signals RPO and RNO to the output transformer 180 through the cascode differential output terminals CO1 and CO2 and further to the antenna 130 through the output transformer 180.

Under the back off power output mode, the cascode control circuit 200 generates the upper driving voltage VD1 and the lower driving voltage VD2 each having a ground voltage level according to the mode control signal MS such that the first upper N-type transistor MN11, the first lower N-type transistor MN12, the second upper N-type transistor MN21 and the second lower N-type transistor MN22 turn off.

As a result, the cascode power amplifier 190A is deactivated under the back off power output mode and does not perform power amplifying on the differential radio frequency input signals RPI and RNI.

Reference is now made to FIG. 2B at the same time. FIG. 2B illustrates a diagram of a waveform of the differential radio frequency output signal RPO outputted after the cascode power amplifier 190A performs power amplifying according to an embodiment of the present invention.

In FIG. 2B, the X-axis stands for the time and the Y-axis stands for the voltage. It is appreciated that the waveform of the differential radio frequency output signal RNO is similar to the waveform of the differential radio frequency output signal RPO, in which only the phases thereof have a difference. As a result, the waveform of the differential radio frequency output signal RNO is not further illustrated.

Since the load that the cascode differential output terminals CO1 and CO2 of the cascode power amplifier 190A in FIG. 2A electrically coupled to is an inductor (i.e., the first side inductor 185A) that is able to store energy, the largest swing SW of the differential radio frequency output signal RPO outputted therefrom is twice of the voltage of the power supply terminal VDD, as illustrated in FIG. 2B, and is expressed by 2VDD. The amplitude AW of the differential radio frequency output signal RPO is the half of the largest swing SW and is expressed by VDD.

Under such a condition, the first upper N-type transistor MN11 and the second upper N-type transistor MN21 included by the cascode power amplifier 190A in FIG. 2A provide the first lower N-type transistor MN12 and the second lower N-type transistor MN22 a better voltage-withstanding ability. Such a mechanism prevents the first lower N-type transistor MN12 and the second lower N-type transistor MN22 from breakdown under the condition that a larger output voltage swing is presented.

Under such a condition, the output power of the differential radio frequency output signals RPO and RNO can be generated by calculating a square of the amplitude AW of the differential radio frequency output signal RPO and further dividing the calculation result by 2 times of the output impedance. When the output impedance is Ro, the output power of the cascode power amplifier 190A is expressed by the following equation:

POC=(VDD)²/(2Ro) (equation 1)

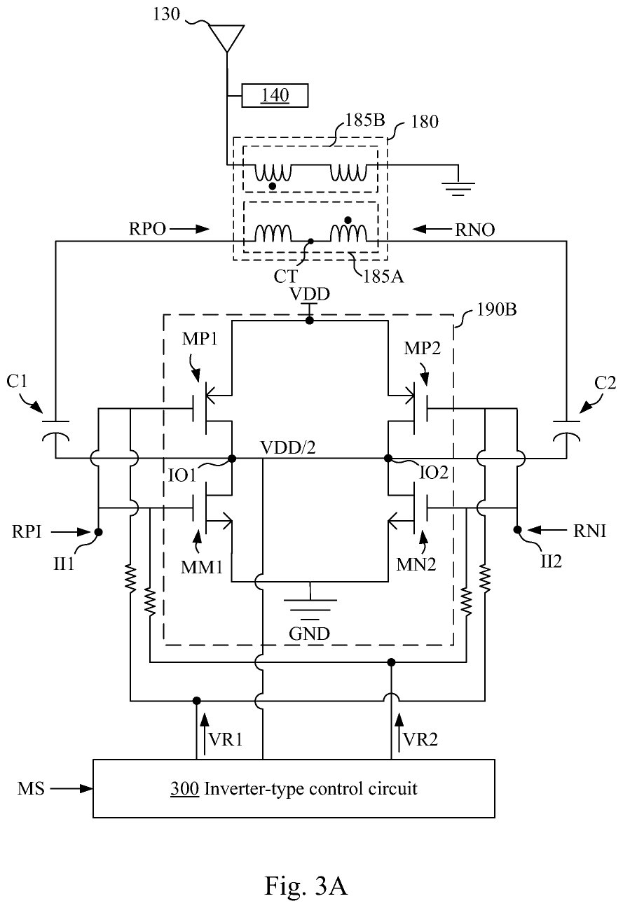

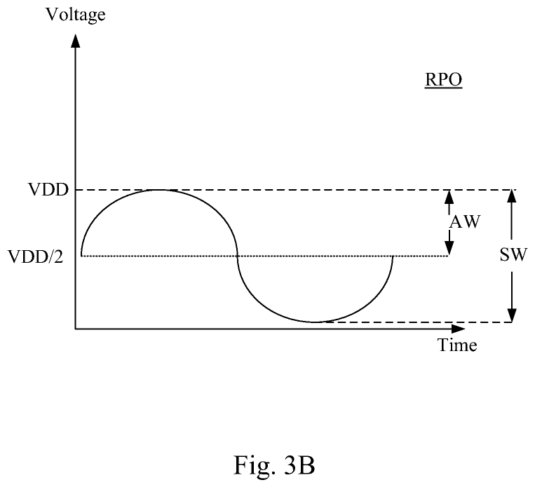

Reference is now made to FIG. 3A. FIG. 3A illustrates a more detailed circuit diagram of the inverter-type power amplifier 190B, the output transformer 180 and the antenna 130 in FIG. 1 according to an embodiment of the present invention.

As illustrated in FIG. 3A, the inverter-type power amplifier 190B is electrically coupled between a pair of inverter-type differential input terminals II1 and II2 and a pair of inverter-type differential output terminals IO1 and IO2 and is electrically coupled to the first side inductor 185A through the inverter-type differential output terminals IO1 and IO2.

The inverter-type power amplifier 190B includes a first inverter branch circuit and a second inverter branch circuit. The first inverter branch circuit includes a first P-type transistor MP1 and a first N-type transistor MM1 coupled in series between the power supply terminal VDD and the ground terminal GND. The first P-type transistor MP1 and the first N-type transistor MM1 are electrically coupled together through a first output terminal (which is the inverter-type differential output terminal IO1) of the inverter-type differential output terminals. The second inverter branch circuit includes a second P-type transistor MP2 and a second N-type transistor MM2 coupled in series between the power supply terminal VDD and the ground terminal GND. The second P-type transistor MP2 and the second N-type transistor MM2 are electrically coupled together through a second output terminal (which is the inverter-type differential output terminal IO2) of the inverter-type differential output terminals.

The first P-type transistor MP1 and the second P-type transistor MP2 are controlled by an upper driving voltage VR1. More specifically, the gates of the first P-type transistor MP1 and the second P-type transistor MP2 are configured to receive the upper driving voltage VR1 that is a direct current voltage to be turned on or turned off according to the upper driving voltage VR1.

The first N-type transistor MM1 and the second N-type transistor MM2 are controlled by a lower driving voltage VR2. More specifically, the gates of the first N-type transistor MM1 and the second N-type transistor MM2 are configured to receive the lower driving voltage VR2 that is a direct current voltage to be turned on or turned off according to the lower driving voltage VR2.

The first P-type transistor MP1 and the first N-type transistor MM1 receive a first signal (which is a differential radio frequency input signal RPI) of differential radio frequency input signals from a first input terminal (which is the inverter-type differential input terminal II1) of the inverter-type differential input terminals. More specifically, the gates of the first P-type transistor MP1 and the first N-type transistor MM1 are configured to receive the differential radio frequency input signal RPI that is an alternating current.

The second P-type transistor MP2 and the second N-type transistor MM2 receive a second signal (which is a differential radio frequency input signal RNI) of the differential radio frequency input signals from a second input terminal (which is the inverter-type differential input terminal II2) of the inverter-type differential input terminals. More specifically, the gates of the second P-type transistor MP2 and the second N-type transistor MM2 are configured to receive differential radio frequency input signal RNI that is an alternating current.

The inverter-type power amplifier 190B further includes an the inverter-type control circuit 300 configured to generate the upper driving voltage VR1 and the lower driving voltage VR2 according to the mode control signal MS to control the turn-on and turn-off of each of the transistors. The mode control circuit 170 is configured to generate the mode control signal MS to an inverter-type control circuit 300 of the inverter-type power amplifier 190B such that the inverter-type power amplifier 190B operates in one of the normal power output mode and the back off power output mode.

More specifically, under the normal power output mode, the inverter-type control circuit 300 generates the upper driving voltage VR1 having the non-ground voltage level and the lower driving voltage VR2 having the ground voltage level according to the mode control signal MS such that the first P-type transistor MP1, the second P-type transistor MP2, the first N-type transistor MM1 and the second N-type transistor MM2 turn off.

As a result, the inverter-type power amplifier 190B is deactivated under the normal power output mode and does not perform power amplifying on the differential radio frequency input signals RPI and RNI.

Under the back off power output mode, the inverter-type control circuit 300 generates the upper driving voltage VR1 having the ground voltage level and the lower driving voltage VR2 having the non-ground voltage level according to the mode control signal MS such that the first P-type transistor MP1, the second P-type transistor MP2, the first N-type transistor MM1 and the second N-type transistor MM2 turn on.

As a result, the inverter-type power amplifier 190B is activated under the back off power output mode to receive the differential radio frequency input signals RPI and RNI through the cascode differential input terminals II1 and II2 to perform power amplifying thereon and output the amplified differential radio frequency output signals RPO and RNO to the output transformer 180 through the inverter-type differential output terminals IO1 and IO2 and further to the antenna 130 through the output transformer 180.

In an embodiment, the inverter-type control circuit 300 is further configured to provide a common mode feedback mechanism to provide a direct current voltage that is a half of a voltage of the power supply terminal VDD to the inverter-type differential output terminals IO1 and IO2.

The inverter-type power amplifier 190B further includes a pair of capacitors C1 and C2 disposed between the inverter-type differential output terminals IO1 and IO2 and the first side inductor 185A. In FIG. 2, the center tap CT of the first side inductor 185A is electrically coupled to the power supply terminal VDD. As a result, the disposition of the capacitors C1 and C2 provides an isolation mechanism to keep such a connection from affecting the components in the inverter-type power amplifier 190B.

Reference is now made to FIG. 3B at the same time. FIG. 3B illustrates a diagram of a waveform of the differential radio frequency output signal RPO outputted after the inverter-type power amplifier 190B performs power amplifying according to an embodiment of the present invention.

In FIG. 3B, the X-axis stands for the time and the Y-axis stands for the voltage. It is appreciated that the waveform of the differential radio frequency output signal RNO is similar to the waveform of the differential radio frequency output signal RPO, in which only the phases thereof have a difference. As a result, the waveform of the differential radio frequency output signal RNO is not further illustrated.

Since the inverter-type differential output terminals IO1 and IO2 of the inverter-type power amplifier 190B in FIG. 3A are not electrically coupled to the load that is an inductor, the largest swing SW of the differential radio frequency output signal RPO outputted therefrom equals to the voltage of the power supply terminal VDD, as illustrated in FIG. 3B, and is expressed by VDD. The amplitude AW of the differential radio frequency output signal RPO is the half of the largest swing SW and is expressed by VDD/2.

More specifically, since the direct current voltage that is the half of the voltage of the power supply terminal VDD is provided to the inverter-type differential output terminals IO1 and IO2 according to the common mode feedback mechanism of the inverter-type control circuit 300, the positive half period of the differential radio frequency input signals RPI and RNI received by the inverter-type differential input terminals II1 and II2 make the first N-type transistor MM1 and the second N-type transistor MM2 turn on and make the first P-type transistor MP1 and the second P-type transistor MP2 turn off. The inverter-type differential output terminals IO1 and IO2 are pulled to the ground voltage level GND.

On the other hand, the negative half period of the differential radio frequency input signals RPI and RNI received by the inverter-type differential input terminals II1 and II2 make the first N-type transistor MM1 and the second N-type transistor MM2 turn off and make the first P-type transistor MP1 and the second P-type transistor MP2 turn on. The inverter-type differential output terminals IO1 and IO2 are pulled to the voltage level of the power supply terminal VDD.

Under such a condition, the output power of the differential radio frequency output signals RPO and RNO can be generated by calculating a square of the amplitude AW of the differential radio frequency output signal RPO and further dividing the calculation result by 2 times of the output impedance. When the output impedance is Ro, the output power of the inverter-type power amplifier 190B is expressed by the following equation:

POI=(VDD/2)²/(2Ro)=(VDD)²/(8Ro)) (equation 2)

As a result, based on the equation 1 and the equation 2, the difference between the output power of the cascode power amplifier 190A and the output power of the inverter-type power amplifier 190B can be calculated by the following equation:

10×log(POC/POI)=6 dB (equation 3)

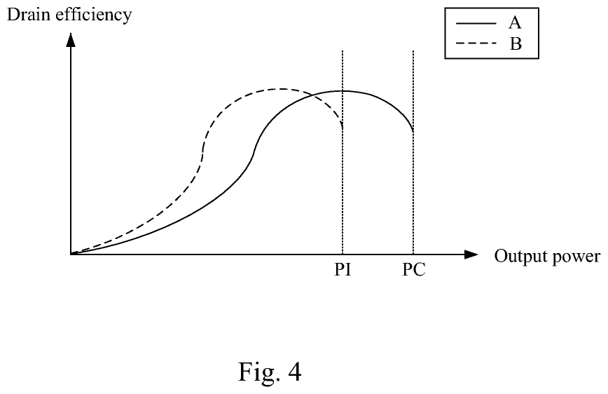

Reference is now made to FIG. 4. FIG. 4 illustrates a diagram of the relation between the output power and a drain efficiency of each of the cascode power amplifier 190A and the inverter-type power amplifier 190B according to an embodiment of the present invention. In FIG. 4, the X-axis stands for the output power and the Y-axis stands for the drain efficiency. The curve A illustrated by a solid line corresponds to the cascode power amplifier 190A. The curve B illustrated by a dashed line corresponds to the inverter-type power amplifier 190B.

As illustrated in FIG. 4, the maximum output power of the cascode power amplifier 190A is labeled as PC. The maximum output power of the inverter-type power amplifier 190B is labeled as PI. In general, the inverter-type power amplifier 190B has the output power that is smaller than the output power of the cascode power amplifier 190A by a value of such as but not limited to 6 dB calculated based on equation 3. However, the inverter-type power amplifier 190B has the drain efficiency that is substantially the same as the drain efficiency of the cascode power amplifier 190A. It is appreciated that the drain efficiency is the efficiency of the amplifier that converts a direct current input to an alternating current output and can be calculated by a ratio between the output power and the direct current power consumption.

More specifically, when the size (e.g., the aspect ratio) of each of the components in the cascode power amplifier 190A and the inverter-type power amplifier 190B is properly configured, the drain efficiency of the inverter-type power amplifier 190B from the minimum output power to the maximum output power (the waveform of the curve B) is substantially the same as the drain efficiency of the cascode power amplifier 190A from the minimum output power to the maximum output power (the waveform of the curve A).

It is appreciated that the term “substantially” means that a difference within a tolerable range can exist between the drain efficiencies of the cascode power amplifier 190A and the inverter-type power amplifier 190B. The drain efficiencies thereof are not necessarily completely the same.

As a result, by using the control of the mode control signal MS, the power amplification output circuit 160 can activate the cascode power amplifier 190A under the normal power output mode to perform power amplifying on the differential radio frequency input signals RPI and RNI to generate the differential radio frequency output signals RPO and RNO. Besides, the power amplification output circuit 160 can activate the inverter-type power amplifier 190B under the back off power output mode to perform power amplifying on the differential radio frequency input signals RPI and RNI to output the differential radio frequency output signals RPO and RNO with a smaller power.

Based on such an output method, the power amplification output circuit 160 performs power amplifying under the back off power output mode when an input power of the differential radio frequency input signals RPI and RNI is too large to avoid the overload condition, keep the linearity of the output power and maintain the drain efficiency same as the drain efficiency under the normal power output mode at the same time.

It is appreciated that the embodiments described above are merely an example. In other embodiments, it is appreciated that many modifications and changes may be made by those of ordinary skill in the art without departing, from the spirit of the invention.

In summary, the signal transmission apparatus and the power amplification output circuit of the present invention perform power amplifying on differential radio frequency input signals by using a cascode power amplifier and an inverter-type power amplifier respectively under a normal power output mode and a back off power output mode. The overload caused by the input power of the differential radio frequency input signals that is too large can be avoided under the back off power output mode of the power amplification output circuit, and the drain efficiency under the back off power output mode can be kept to be the same as the drain efficiency under the normal power output mode.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. A power amplification output circuit comprising:
an output transformer comprising a first side inductor and a second side inductor;
a cascode power amplifier electrically coupled between a pair of cascode differential input terminals and a pair of cascode differential output terminals and electrically coupled to the first side inductor through the pair of cascode differential output terminals; and
an inverter-type power amplifier electrically coupled between a pair of inverter-type differential input terminals and a pair of inverter-type differential output terminals and electrically coupled to the first side inductor through the pair of inverter-type differential output terminals;
wherein the cascode power amplifier is activated under a normal power output mode to receive a pair of differential radio frequency input signals through the pair of cascode differential input terminals to perform power amplifying to the pair of differential radio frequency input signals and output the amplified differential radio frequency input signals to the output transformer through the pair of cascode differential output terminals and further to an antenna through the second side inductor;
the inverter-type power amplifier is activated under a back off power output mode to receive the pair of differential radio frequency input signals through the pair of inverter-type differential input terminals to perform power amplifying to the pair of differential radio frequency input signals and output the amplified differential radio frequency input signals to the output transformer through the pair of inverter-type differential output terminals and further to the antenna through the second side inductor.

2. The power amplification output circuit of claim 1, wherein the cascode power amplifier comprises:
a first cascode branch circuit comprising a first upper N-type transistor and a first lower N-type transistor coupled in series between a first terminal of the pair of cascode differential input terminals and a ground terminal; and
a second cascode branch circuit comprising a second upper N-type transistor and a second lower N-type transistor coupled in series between a second terminal of the pair of cascode differential input terminals and the ground terminal;
wherein the first upper N-type transistor and the second upper N-type transistor are electrically coupled to a power supply terminal through a center tap of the first side inductor and are controlled by an upper driving voltage;
the first lower N-type transistor and the second lower N-type transistor are controlled by a lower driving voltage and receive the pair of differential radio frequency input signals from the pair of cascode differential input terminals.

3. The power amplification output circuit of claim 2, wherein the cascode power amplifier further comprises a cascode control circuit configured to generate the upper driving voltage and the lower driving voltage each having a non-ground voltage level under the normal power output mode according to a mode control signal, and generate the upper driving voltage and the lower driving voltage each having a ground voltage level under the back off power output mode.

4. The power amplification output circuit of claim 1, wherein the inverter-type power amplifier comprises:
a first inverter branch circuit comprising a first P-type transistor and a first N-type transistor coupled in series between a power supply terminal and a ground terminal and the first P-type transistor and the first N-type transistor are electrically coupled together through a first output terminal of the pair of inverter-type differential output terminals; and
a second inverter branch circuit comprising a second P-type transistor and a second N-type transistor coupled in series between the power supply terminal and the ground terminal and the second P-type transistor and the second N-type transistor are electrically coupled together through a second output terminal of the pair of inverter-type differential output terminals;
wherein the first P-type transistor and the second P-type transistor are controlled by an upper driving voltage and the first N-type transistor and the second N-type transistor are controlled by a lower driving voltage;
the first P-type transistor and the first N-type transistor receive a first signal of the pair of differential radio frequency input signals from a first input terminal of the pair of inverter-type differential input terminals, and the second P-type transistor and the second N-type transistor receive a second signal of the pair of differential radio frequency input signals from a second input terminal of the pair of inverter-type differential input terminals.

5. The power amplification output circuit of claim 4, wherein the inverter-type power amplifier further comprises an inverter-type control circuit configured to, according to a mode control signal, generate the upper driving voltage having a non-ground voltage level and the lower driving voltage having a ground voltage level under the normal power output mode and generate the upper driving voltage having the ground voltage level and the lower driving voltage having the non-ground voltage level under the back off power output mode.

6. The power amplification output circuit of claim 5, wherein the inverter-type control circuit is further configured to provide a common mode feedback mechanism to provide a direct current voltage that is a half of a voltage of the power supply terminal to the pair of inverter-type differential output terminals.

7. The power amplification output circuit of claim 4, wherein the inverter-type power amplifier further comprises a pair of capacitors disposed between the pair of inverter-type differential output terminals and the first side inductor.

8. The power amplification output circuit of claim 1, wherein the inverter-type power amplifier has an output power smaller than the output power of the cascode power amplifier, and the inverter-type power amplifier has a drain efficiency substantially the same as the drain efficiency of the cascode power amplifier.

9. A signal transmission apparatus comprising:
a signal source circuit configured to generate a pair of differential radio frequency input signals;
a power amplification output circuit, comprising:
an output transformer comprising a first side inductor and a second side inductor;
a cascode power amplifier electrically coupled between a pair of cascode differential input terminals and a pair of cascode differential output terminals and electrically coupled to the first side inductor through the pair of cascode differential output terminals; and
an inverter-type power amplifier electrically coupled between a pair of inverter-type differential input terminals and a pair of inverter-type differential output terminals and electrically coupled to the first side inductor through the pair of inverter-type differential output terminals; and
a mode control circuit configured to generate a mode control signal to the cascode power amplifier and the inverter-type power amplifier such that the cascode power amplifier and the inverter-type power amplifier operate in one of a normal power output mode and a back off power output mode;
wherein the cascode power amplifier is activated under the normal power output mode to receive the pair of differential radio frequency input signals through the pair of cascode differential input terminals to perform power amplifying to the pair of differential radio frequency input signals and output the amplified differential radio frequency input signals to the output transformer through the pair of cascode differential output terminals and further to an antenna through the second side inductor;
the inverter-type power amplifier is activated under the back off power output mode to receive the pair of differential radio frequency input signals through the pair of inverter-type differential input terminals to perform power amplifying to the pair of differential radio frequency input signals and output the amplified differential radio frequency input signals to the output transformer through the pair of inverter-type differential output terminals and further to the antenna through the second side inductor.

10. The signal transmission apparatus of claim 9, wherein the cascode power amplifier comprises:
a first cascode branch circuit comprising a first upper N-type transistor and a first lower N-type transistor coupled in series between a first terminal of the pair of cascode differential input terminals and a ground terminal; and
a second cascode branch circuit comprising a second upper N-type transistor and a second lower N-type transistor coupled in series between a second terminal of the pair of cascode differential input terminals and the ground terminal;
wherein the first upper N-type transistor and the second upper N-type transistor are electrically coupled to a power supply terminal through a center tap of the first side inductor and are controlled by an upper driving voltage;
the first lower N-type transistor and the second lower N-type transistor are controlled by a lower driving voltage and receive the pair of differential radio frequency input signals from the pair of cascode differential input terminals.

11. The signal transmission apparatus of claim 10, wherein the cascode power amplifier further comprises a cascode control circuit configured to generate the upper driving voltage and the lower driving voltage each having a non-ground voltage level under the normal power output mode according to a mode control signal, and generate the upper driving voltage and the lower driving voltage each having a ground voltage level under the back off power output mode.

12. The signal transmission apparatus of claim 11, wherein the inverter-type power amplifier comprises:
a first inverter branch circuit comprising a first P-type transistor and a first N-type transistor coupled in series between a power supply terminal and a ground terminal and the first P-type transistor and the first N-type transistor are electrically coupled together through a first output terminal of the pair of inverter-type differential output terminals; and
a second inverter branch circuit comprising a second P-type transistor and a second N-type transistor coupled in series between the power supply terminal and the ground terminal and the second P-type transistor and the second N-type transistor are electrically coupled together through a second output terminal of the pair of inverter-type differential output terminals;
wherein the first P-type transistor and the second P-type transistor are controlled by an upper driving voltage and the first N-type transistor and the second N-type transistor are controlled by a lower driving voltage;
the first P-type transistor and the first N-type transistor receive a first signal of the pair of differential radio frequency input signals from a first input terminal of the pair of inverter-type differential input terminals, and the second P-type transistor and the second N-type transistor receive a second signal of the pair of differential radio frequency input signals from a second input terminal of the pair of inverter-type differential input terminals.

13. The signal transmission apparatus of claim 12, wherein the inverter-type power amplifier further comprises an inverter-type control circuit configured to, according to a mode control signal, generate the upper driving voltage having a non-ground voltage level and the lower driving voltage having a ground voltage level under the normal power output mode and generate the upper driving voltage having the ground voltage level and the lower driving voltage having the non-ground voltage level under the back off power output mode.

14. The signal transmission apparatus of claim 13, wherein the inverter-type control circuit is further configured to provide a common mode feedback mechanism to provide a direct current voltage that is a half of a voltage of the power supply terminal to the pair of inverter-type differential output terminals.

15. The signal transmission apparatus of claim 12, wherein the inverter-type power amplifier further comprises a pair of capacitors disposed between the pair of inverter-type differential output terminals and the first side inductor.

16. The signal transmission apparatus of claim 9, wherein the inverter-type power amplifier has an output power smaller than the output power of the cascode power amplifier, and the inverter-type power amplifier has a drain efficiency substantially the same as the drain efficiency of the cascode power amplifier.
